(19) United States
(12) Patent Application Publication
(10) Pub. No.: US 2016/0079494 A1
(43) Pub. Date: Mar. 17, 2016

(54) LIGHT EMITTING ELEMENT STRUCTURE

(71) Applicant: Genesis Photonics Inc., Tainan City (TW)

(72) Inventors: Shao-Ying Ting, Tainan City (TW); Kuan-Chieh Huang, Tainan City (TW); Jing-En Huang, Tainan City (TW); Yi-Ru Huang, Tainan City (TW)

(21) Appl. No.: 14/582,195

(22) Filed: Dec. 24, 2014

(30) Foreign Application Priority Data
Sep. 15, 2014 (TW) 103216334

(51) Int. Cl. H01L 33/58; H01L 33/50

(52) U.S. Cl. CPC H01L 33/58; H01L 33/507

(57) ABSTRACT

A light emitting element structure includes a light emitting unit configured to emit light; a package unit configured to cover the light emitting unit; a transparent light guide structure arranged on the package unit; and a first periodic sub-wavelength microstructure formed on the transparent light guide structure, wherein a plurality of holes of the first periodic sub-wavelength microstructure form a periodic pattern, and a distance between two adjacent holes of the first periodic sub-wavelength microstructure is smaller than λ/n, λ is a peak wavelength of light passing through the package unit from the light emitting unit, and n is a refractive index of the first periodic sub-wavelength microstructure.

### BACKGROUND OF THE INVENTION

1. Field of the Invention

The present invention relates to a light emitting element structure, and more particularly, to a light emitting element structure capable of increasing light extraction efficiency and light divergence angle.

2. Description of the Prior Art

Since light emitting diodes (LEDs) have advantages of long service life, small size and low power consumption, the light emitting diodes are widely used in various kinds of illumination devices and display devices. Generally, a light emitting diode structure usually comprises a light emitting unit and a package unit. The light emitting unit is a light emitting diode die for emitting light. The package unit covers the light emitting unit, and may comprise wavelength conversion particles for converting a peak wavelength of light emitted from the light emitting unit.

However, in the light emitting diode structure of the prior art, a difference between a refractive index of the package unit and a refractive index of air is large, such that partial light emitted from the light emitting unit is totally reflected by an interface between the package unit and air. Therefore, the light emitting diode structure of the prior art has lower light extraction efficiency. Moreover, the light emitting diode structure of the prior art also has a smaller light divergence angle, so as to decrease illumination efficiency of the light emitting diode structure.

### SUMMARY OF THE INVENTION

An objective of the present invention is to provide a light emitting element structure capable of increasing light extraction efficiency and light divergence angle, in order to solve problems of the prior art.

A light emitting element structure of the present invention comprises a light emitting unit, configured to emit light; a package unit, configured to cover the light emitting unit; a transparent light guide structure, arranged on the package unit; and a first periodic sub-wavelength microstructure, formed on the transparent light guide structure, wherein a plurality of holes of the first periodic sub-wavelength microstructure form a periodic pattern, and a distance between two adjacent holes of the first periodic sub-wavelength microstructure is smaller than λ/n, λ is a peak wavelength of light passing through the package unit from the light emitting unit, and n is a refractive index of the first periodic sub-wavelength microstructure.

In an embodiment of the present invention, the package unit comprises a package resin, and a plurality of wavelength conversion particles distributed in the package resin, for converting a peak wavelength of light emitted from the light emitting unit.

In an embodiment of the present invention, the plurality of wavelength conversion particles are fluorescent powders.

In an embodiment of the present invention, the plurality of wavelength conversion particles are quantum dots.

In an embodiment of the present invention, the first periodic sub-wavelength microstructure is formed by performing etching or deposition on an upper surface of the transparent light guide structure.

In an embodiment of the present invention, the light emitting element structure further comprises a second periodic sub-wavelength microstructure, formed between the transparent light guide structure and the package unit, wherein a plurality of holes of the first periodic sub-wavelength microstructure form a periodic pattern, and a distance between two adjacent holes of the second periodic sub-wavelength microstructure is smaller than λ/m, m is a refractive index of the second periodic sub-wavelength microstructure.

In an embodiment of the present invention, the second periodic sub-wavelength microstructure is formed by performing etching or deposition on a lower surface of the transparent light guide structure.

In an embodiment of the present invention, the light emitting unit is a light emitting diode die.

In contrast to the prior art, the light emitting element structure of the present invention utilizes the transparent light guide structure and the periodic sub-wavelength microstructure to reduce occurrence of total internal reflection for light emitted from the light emitting unit, so as to increase light extraction efficiency of the light emitting element structure. Moreover, the transparent light guide structure of the light emitting element structure of the present invention can increase the light divergence angle of the light emitting element structure, in order to further improve illumination efficiency of the light emitting element structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing alight emitting element structure according to a first embodiment of the present invention.

FIG. 2 is a diagram showing a first periodic sub-wavelength microstructure of the present invention.

FIG. 3 is a diagram showing alight emitting element structure according to a second embodiment of the present invention.

### DETAILED DESCRIPTION

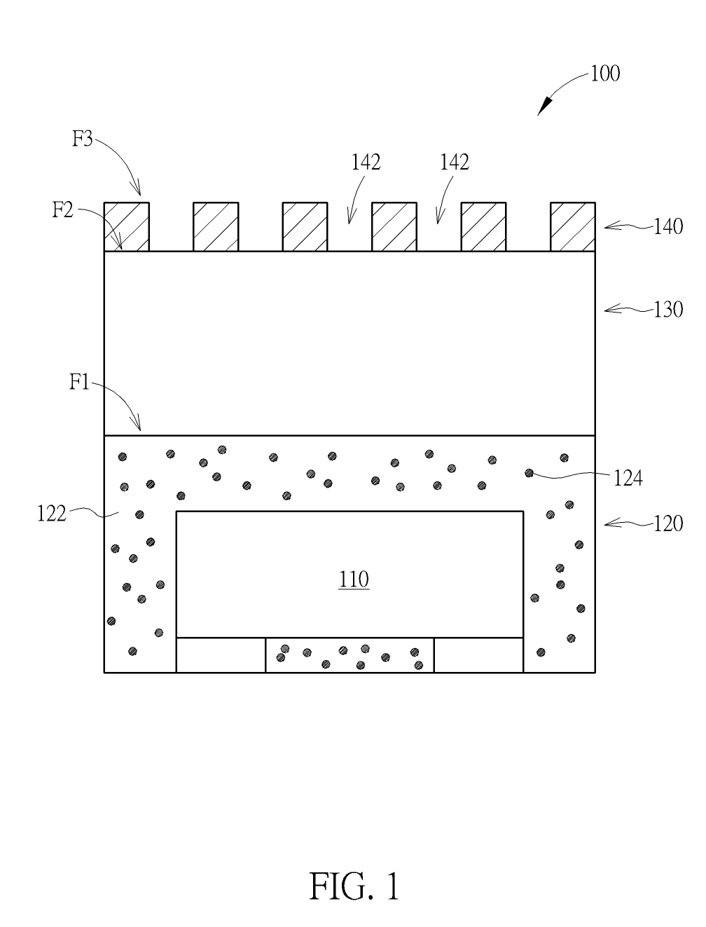

Please refer to FIG. 1. FIG. 1 is a diagram showing a light emitting element structure according to a first embodiment of the present invention. As shown in FIG. 1, the light emitting element structure 100 of the present invention comprises a light emitting unit 110, a package unit 120, a transparent light guide structure 130 and a first periodic sub-wavelength microstructure 140. The light emitting unit 110 is configured to emit light. In the embodiment of the present invention, the light emitting unit 110 is a light emitting diode die, but the present invention is not limited to it. The package unit 120 is configured to cover the light emitting unit 110, for providing protection. The transparent light guide structure 130 is arranged on the package unit 120. Generally, the transparent light guide structure 130 can be made of glass, silicon or other proper material, and a refractive index of the transparent light guide structure 130 is around 1.5, which is between a refractive index of the package unit (around 1.6) and a refractive index of air (around 1). Since the refractive index of the transparent light guide structure 130 is close to the refractive index of the package unit 120, when the light emitted from the light emitting unit 110 arrives at the transparent light guide structure 130 through the package unit 120, possibility of light being totally reflected by an interface F1 between the transparent light guide structure 130 and the package unit 120 is smaller, such that light extraction efficiency of the light emitting element structure 100 is increased. Moreover, the transparent light guide structure 130 can further increase a light divergence angle of the light emitting element structure 100.

The first periodic sub-wavelength microstructure 140 is formed on the transparent light guide structure 130. In the embodiment of the present invention, the first periodic sub-wavelength microstructure 140 is formed by etching an upper surface of the transparent light guide structure 130. But in other embodiment of the present invention, the first periodic sub-wavelength microstructure 140 can also be formed by performing a deposition processing or other proper processing (such as laser processing) on the upper surface of the transparent light guide structure 130. Since a plurality of holes 142 of the first periodic sub-wavelength microstructure 140 are filled with air, there are two kinds of materials existing in a layer of the first periodic sub-wavelength microstructure 140. Thus a refractive index of the first periodic sub-wavelength microstructure 140 is between the refractive index of the transparent light guide structure 130 and a refractive index of air, that is to say, the refractive index of the first periodic sub-wavelength microstructure 140 is between 1 and 1.5. Since the refractive index of the first periodic sub-wavelength microstructure 140 is between the refractive index of the transparent light guide structure 130 and the refractive index of air, the refractive index is gradually changed when the light arriving at the air through the transparent light guide structure 130 and the first periodic sub-wavelength microstructure 140. Therefore, when the light emitted from the light emitting unit 110 arrives at the first periodic sub-wavelength microstructure 140 through the transparent light guide structure 130, possibility of light being totally reflected by an interface F2 between the first periodic sub-wavelength microstructure 140 and the transparent light guide structure 130 is smaller. Similarly, when the light emitted from the light emitting unit 110 arrives at the air through the first periodic sub-wavelength microstructure 140, possibility of light being totally reflected by an interface F3 between the air and the first periodic sub-wavelength microstructure 140 is smaller. Therefore, the first periodic sub-wavelength microstructure 140 can further increase the light extraction efficiency of the light emitting element structure 100.

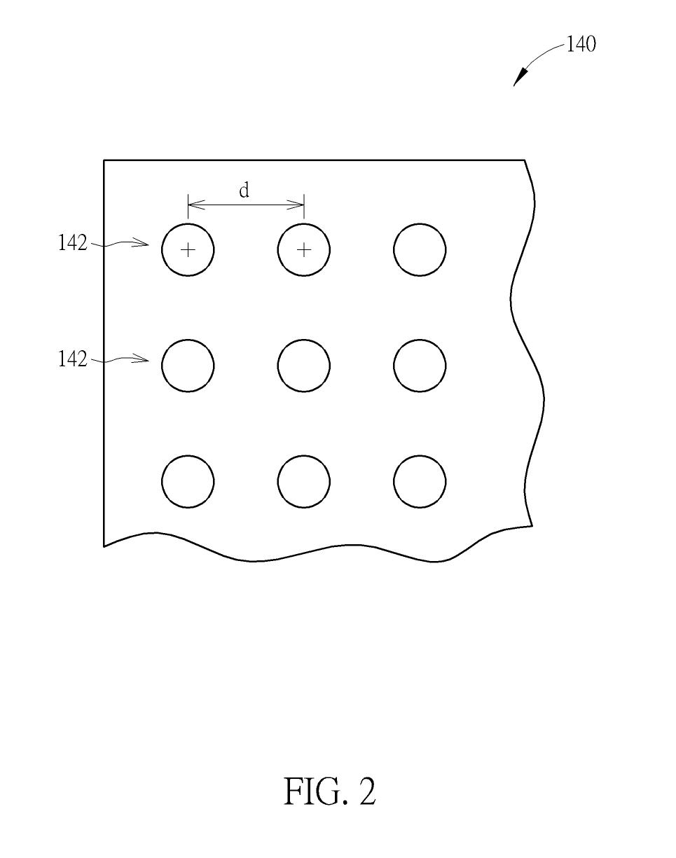

Please refer to FIG. 2. FIG. 2 is a diagram showing the first periodic sub-wavelength microstructure of the present invention. As shown in FIG. 2, the plurality of holes 142 of the first periodic sub-wavelength microstructure 140 form a periodic pattern, and a distance d between two adjacent holes 142 of the first periodic sub-wavelength microstructure 140 is smaller than λ/n, where λ is a peak wavelength of light passing through the package unit 120 from the light emitting unit 110, and n is the refractive index of the first periodic sub-wavelength microstructure 140. Therefore, the first periodic sub-wavelength microstructure 140 can prevent interference or diffraction when the light passing through the first periodic sub-wavelength microstructure 140. On the other hand, the distance d between two adjacent holes 142 is not necessary to be a fixed value. The distance d can also be changed periodically.

In addition, in the above embodiment, the package unit 120 comprises a package resin 122 and a plurality of wavelength conversion particles 124 distributed in the package resin 122. The plurality of wavelength conversion particles 124 are configured to convert a peak wavelength of the light emitted from the light emitting unit 110. For example, the plurality of wavelength conversion particles 124 can be fluorescent powders or quantum dots, and the plurality of wavelength conversion particles 124 can convert the peak wavelength of the light emitted from the light emitting unit 110 to a predetermined peak wavelength according to design requirements. However, in other embodiments of the present invention, the package unit 120 may not comprise the wavelength conversion particles 124, the package unit 120 can only comprise the package resin 122 for protecting the light emitting unit 110, such that a peak wavelength of light emitted from the light emitting element structure 100 is identical to the peak wavelength of light emitted from the light emitting unit 110.

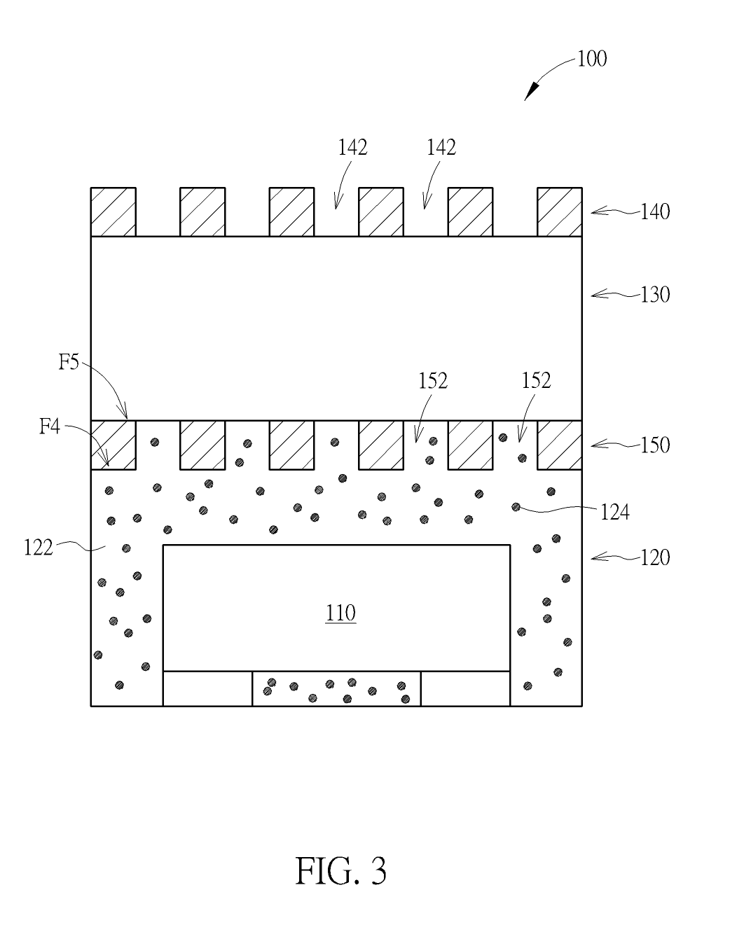

Please refer to FIG. 3. FIG. 3 is a diagram showing a light emitting element structure according to a second embodiment of the present invention. As shown in FIG. 3, apart from the light emitting unit 110, the package unit 120, the transparent light guide structure 130 and the first periodic sub-wavelength microstructure 140, the light emitting element structure 100′ of the present invention further comprises a second periodic sub-wavelength microstructure 150, arranged between the transparent light guide structure 130 and the package unit 120. In the embodiment of the present invention, the second periodic sub-wavelength microstructure 150 is formed by etching a lower surface of the transparent light guide structure 130. But in other embodiment of the present invention, the second periodic sub-wavelength microstructure 150 can also be formed by performing a deposition processing or other proper processing (such as laser processing) on the lower surface of the transparent light guide structure 130. Since a plurality of holes 152 of the second periodic sub-wavelength microstructure 150 are filled with the package unit 120, a refractive index of the second periodic sub-wavelength microstructure 150 is between the refractive index of the transparent light guide structure 130 and the refractive index of package unit 120, that is to say, the refractive index of the second periodic sub-wavelength microstructure 150 is between 1.5 and 1.6.

According to the above arrangement, since the refractive index of the second periodic sub-wavelength microstructure 150 is between the refractive index of the transparent light guide structure 130 and the refractive index of the package unit 120, the refractive index is gradually changed when the light passing through the package unit 120, the second periodic sub-wavelength microstructure 150 and the transparent light guide structure 130. Therefore, when the light emitted from the light emitting unit 110 arrives at the second periodic sub-wavelength microstructure 150 through the package unit 120, possibility of light being totally reflected by an interface F4 between the second periodic sub-wavelength microstructure 150 and the package unit 120 is smaller. Similarly, when the light emitted from the light emitting unit 110 arrives at the transparent light guide structure 130 through the second periodic sub-wavelength microstructure 150, possibility of light being totally reflected by an interface F5 between the transparent light guide structure 130 and the second periodic sub-wavelength microstructure 150 is smaller. Therefore, the second periodic sub-wavelength microstructure 150 can reduce occurrence of total internal reflection for light between the transparent light guide structure 130 and the package unit 120, so as to further increase the light extraction efficiency of the light emitting element structure 100′.

Moreover, similarly to the first periodic sub-wavelength microstructure 140, the plurality of holes 152 of the second periodic sub-wavelength microstructure 150 also form a periodic pattern, and a distance between two adjacent holes 152 of the second periodic sub-wavelength microstructure 150 is smaller than λ/m, where λ is the peak wavelength of light passing through the package unit 120 from the light emitting unit 110, and m is the refractive index of the second periodic sub-wavelength microstructure 150. Therefore, the second periodic sub-wavelength microstructure 150 can prevent interference or diffraction when the light passing through the second periodic sub-wavelength microstructure 150.

In addition, in the second embodiment of the light emitting element structure of the present invention, when the package unit 120 comprises the plurality of wavelength conversion particles 124, the plurality of wavelength conversion particles 124 are quantum dots, and the quantum dots can be filled in the plurality of holes 152 of the second periodic sub-wavelength microstructure 150.

On the other hand, in the periodic pattern formed by the plurality of holes 152 of the second periodic sub-wavelength microstructure 150, the distance between two adjacent holes 152 is not necessary to be a fixed value. The distance can also be changed periodically. And the periodic pattern of the second periodic sub-wavelength microstructure 150 is not necessary to be identical to the periodic pattern of the first periodic sub-wavelength microstructure 140.

In contrast to the prior art, the light emitting element structure of the present invention utilizes the transparent light guide structure and the periodic sub-wavelength microstructure to reduce occurrence of total internal reflection for light emitted from the light emitting unit, so as to increase light extraction efficiency of the light emitting element structure. Moreover, the transparent light guide structure of the light emitting element structure of the present invention can increase the light divergence angle of the light emitting element structure, in order to further improve illumination efficiency of the light emitting element structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting element structure, comprising:
a light emitting unit, configured to emit light;
a package unit, configured to cover the light emitting unit;
a transparent light guide structure, arranged on the package unit; and
a first periodic sub-wavelength microstructure, formed on the transparent light guide structure, wherein a plurality of holes of the first periodic sub-wavelength microstructure form a periodic pattern, and a distance between two adjacent holes of the first periodic sub-wavelength microstructure is smaller than λ/n, λ is a peak wavelength of light passing through the package unit from the light emitting unit, and n is a refractive index of the first periodic sub-wavelength microstructure.

2. The package structure of claim 1, wherein the package unit comprises:
a package resin; and
a plurality of wavelength conversion particles distributed in the package resin, for converting a peak wavelength of light emitted from the light emitting unit.

3. The package structure of claim 2, wherein the plurality of wavelength conversion particles are fluorescent powders.

4. The package structure of claim 2, wherein the plurality of wavelength conversion particles are quantum dots.

5. The package structure of claim 1, wherein the first periodic sub-wavelength microstructure is formed by performing etching or deposition on an upper surface of the transparent light guide structure.

6. The package structure of claim 1 further comprising:
a second periodic sub-wavelength microstructure, formed between the transparent light guide structure and the package unit, wherein a plurality of holes of the first periodic sub-wavelength microstructure form a periodic pattern, and a distance between two adjacent holes of the second periodic sub-wavelength microstructure is smaller than λ/m, m is a refractive index of the second periodic sub-wavelength microstructure.

7. The package structure of claim 6, wherein the second periodic sub-wavelength microstructure is formed by performing etching or deposition on a lower surface of the transparent light guide structure.

8. The package structure of claim 1, wherein the light emitting unit is a light emitting diode die.
